(19) United States
(12) Patent Application Publication
(10) Pub. No.: US 2015/0345663 A1
(43) Pub. Date: Dec. 3, 2015

(54) Microvalve Device and Manufacturing Method Therefor

(71) Applicants: Tinghou Jiang, Hangzhou (CN); Shengchang ZHANG, Hangzhou (CN); Ning DENG, Hangzhou (CN); Zheyao WANG, Hangzhou (CN); Peiyi CHEN, Hangzhou (CN)

(72) Inventors: Tinghou Jiang, Hangzhou (CN); Shengchang ZHANG, Hangzhou (CN); Ning DENG, Hangzhou (CN); Zheyao WANG, Hangzhou (CN); Peiyi CHEN, Hangzhou (CN)

(21) Appl. No.: 14/758,862

(22) PCT Filed: Jan. 11, 2013
(86) PCT No.: PCT/CN2013/070392

§ 371 Date: Jul. 1, 2015

(51) Int. Cl. F16K 99/00; H01L 41/25

(52) U.S. Cl. CPC F16K 99/0011; F16K 99/0048; F16K 99/0028; H01L 41/25; F16K 2099/008

(57) ABSTRACT

A microvalve device and a manufacturing method therefore are disclosed. The microvalve device includes a body, including a first layer (7) and at least a second layer (8) forming a chamber (8) with the first layer (7), wherein the first layer (7) is provided with at least two fluid ports (4, 5, 6) in fluid communication with the chamber (9); and piezoelectric actuators (1, 2, 3) corresponding to predetermined fluid ports (4, 5, 6), wherein the piezoelectric actuators (1, 2, 3) are arranged in the chamber (9) and strain extending and retracting directions of the piezoelectric actuators are parallel to the first layer (7), wherein free ends of the piezoelectric actuators (1, 2, 3) in the strain extending and retracting directions are used for shielding the fluid ports (4, 5, 6) so as to control opening/closing states of the fluid ports (4, 5, 6).

### TECHNICAL FIELD OF THE INVENTION

The present invention relates to a micro electro mechanical system (MEMS), and particularly to a microvalve device for controlling a fluid, and a manufacturing method for the microvalve device.

### BACKGROUND OF THE INVENTION

A microvalve refers to a micro electro mechanical system (MEMS) processed by using a microelectronic technique. Generally, the size of a core component (an actuator) in the microvalve processed by using the microelectronic technique is in a micrometer range, and a mechanical motion of the actuator is obtained by applying electric excitation to the actuator. Besides, the microvalve may further include other components manufactured or not manufactured by a micromachining technique.

Currently, there are already a variety of microvalve structures used for controlling flowing of a fluid in a fluid passage in a microvalve.

FIG. 1 and FIG. 2 schematically illustrate an existing microvalve device. The microvalve device comprises an electric actuator (not shown) and a movable component 20. A motion of the moveable component 20 is controlled by the electric actuator. The electric actuator may implement a controllable motion by applying an electric signal. The moveable component 20 is provided with a plurality of through holes therein. An opening degree of fluid ports 31 and 33 in the microvalve may be controlled by a motion of the moveable component, there by controlling a rate of a fluid (the fluid flows in a chamber of the microvalve) flowing out of the microvalve to further control a main valve.

A typical actuator consists of a beam with one end fixedly supported. The moveable component is connected to the other end of the beam. The electric actuator is driven by an electric signal to generate an adequate displacement and driving force to drive the moveable component to slide in the chamber, thereby changing a flowing state of a fluid in a control port so as to control the main valve. For example, FIG. 1 and FIG. 2 respectively illustrate different states of the moveable component 20 to control flowing of a fluid at different positions. In the figures, an arrow represents a flow direction of the fluid, Fluid Port 31 is a fluid source port, Fluid Port 32 is a control port and Fluid Port 33 is a reflux port. The size of the electric actuator and the power of an input electric signal may be jointly determined by a displacement which the movable component needs to move, amplification of the microvalve for the displacement and a required driving force.

The microvalve device is disclosed in American patents U.S. Pat. No. 6,494,804, U.S. Pat. No. 6,540,203, U.S. Pat. No. 6,637,722, U.S. Pat. No. 6,694,998, U.S. Pat. No. 6,755,761, U.S. Pat. No. 6,845,962, U.S. Pat. No. 6,994,115 and Chinese patent 200580006045.9 (application number). All content disclosed by the patents above are used for reference here.

During a process of implementing the present invention, inventors found that an existing microvalve device has the following problems: one problem is that a determined control signal can hardly determine a displacement of an electric actuator uniquely, thus resulting in imprecise control of a rate of a fluid, and open-loop control of the microvalve cannot be implemented. Another problem is that a sliding mechanism for controlling three ports is driven by the electric actuator to move integrally, which correlates opening/closing states of the three ports so that an electric signal for controlling a pilot valve and an opening degree of a main valve are not in a linear relation, thereby complicating control on the main valve.

### SUMMARY OF THE INVENTION

A purpose of the present invention is to provide a microvalve device for controlling fluid ports separately and a manufacturing method for the microvalve device.

For this purpose, the present invention provides a microvalve device in one aspect, comprising: a body, at least including a first layer and a second layer forming a chamber with the first layer, wherein the first layer is provided with at least two fluid ports in fluid communication with the chamber; and piezoelectric actuators corresponding to predetermined fluid ports, wherein the piezoelectric actuators are arranged in the chamber and strain extending and retracting directions of the piezoelectric actuators are parallel to the first layer, wherein free ends of the piezoelectric actuators in the strain extending and retracting directions are used for shielding the fluid ports so as to control opening/closing states of the fluid ports.

Further, the fluid ports are long strip-shaped, and the length directions of the fluid ports are vertical to the strain extending and retracting directions of the piezoelectric actuators.

Further, the length directions of the fluid ports have the same orientation. Further, the fluid ports are partly opened or fully opened by the free ends of the piezoelectric actuators in the strain extending and retracting directions when the fluid ports are opened.

Further, the piezoelectric actuators are stack-type piezoelectric ceramics and the thickness directions of the stack-type piezoelectric ceramics are parallel to the first layer.

Further, an opening width of one side of the fluid ports on the first layer which faces to the chamber is smaller or equal to an opening width of one side of the fluid ports on the first layer which faces to outside.

Further, a free end of a second piezoelectric actuator in a strain extending and retracting direction is further used for controlling an opening degree of a second fluid port precisely.

Further, the microvalve device is a pilot microvalve.

Further, the first layer is provided with a first fluid port, the second fluid port and a third fluid port, wherein the first fluid port is a fluid source port, the second fluid port is a control port, and the third fluid port is a reflux port, wherein at least a first piezoelectric actuator corresponding to the first fluid port and a third piezoelectric actuator corresponding to the third fluid port are arranged in the chamber.

Further, a second piezoelectric actuator corresponding to the second fluid port is arranged in the chamber, wherein the first fluid port and the third fluid port are arranged in parallel at an interval, the second fluid port is located between the first fluid port and the third fluid port, and a length direction of the second fluid port is vertical to a length direction of the first fluid port.

Further, the microvalve device is a reversing microvalve. Further, the microvalve device is a stop microvalve. Further, the body only comprises the first layer provided with the fluid ports and the second layer forming the chamber, wherein a bottom wall of the chamber of the second layer is provided with alignment concave areas thereon, and the piezoelectric actuators are provided with locating parts located in the alignment concave areas.

Further, the piezoelectric actuators are adhesively fixed to the second layer.

The present invention further provides a manufacturing method for a microvalve device, comprising the following steps: manufacturing a first layer provided with at least two fluid ports; manufacturing a second layer provided with a chamber; placing piezoelectric actuators in the chamber of the second layer, and aligning and adhering the piezoelectric actuators with the second layer; and combining the first layer and the second layer to form the microvalve device, wherein strain extending and retracting directions of the piezoelectric actuators are parallel to the first layer, wherein free ends of the piezoelectric actuators in the strain extending and retracting directions are used for shielding the fluid ports so as to control opening/closing states of the fluid ports.

Further, the step of manufacturing the second layer provided with the chamber further comprising forming alignment concave areas of the piezoelectric actuators on a bottom wall of the chamber.

The present invention further provides a microvalve device, comprising a first layer provided with fluid ports and laminated piezoelectric actuators arranged at one side of the first layer; strain extending and retracting directions of the piezoelectric actuators are parallel to the first layer; free ends of the piezoelectric actuators in the strain extending and retracting directions are used for shielding the fluid ports so as to control opening/closing states of the fluid ports.

In the present invention, free ends of piezoelectric actuators in strain extending and retracting directions shield fluid ports directly, and a purpose of directly controlling fluid ports is achieved by controlling strain extension and retraction of the piezoelectric actuators. Compared with a microvalve device of the prior art, a structure of a microvalve device of the present invention is evidently simplified, thus facilitating micromachining while improving the reliability of the microvalve device.

Besides the aforementioned purpose, characteristics, and advantages, the present invention has other purposes, characteristics, and advantages, and detailed illustration will be further given in combination with the accompanying drawings.

### BRIEF DESCRIPTION OF THE DRAWINGS

The accompanying drawings, which constitute a part of the specification and are used for further understanding the present invention, illustrate preferred embodiments of the present invention and are used for illustrating the principle of the present invention together with the specification. In the drawings:

FIG. 1 is a schematic diagram of a microvalve at a first control state according to the prior art;

FIG. 2 is a schematic diagram of a microvalve at a second control state according to the prior art;

FIG. 3 is a schematic diagram of a microvalve device at a first control state according to a preferred embodiment of the present invention;

FIG. 4 is a sectional view of the microvalve device as shown in FIG. 3;

FIG. 5 is a schematic diagram of a microvalve device at a second control state according to a preferred embodiment of the present invention;

FIG. 6 is a sectional view of the microvalve device as shown in FIG. 5;

FIG. 7 is a structural diagram of a microvalve device according to another preferred embodiment of the present invention; and

FIG. 8A to FIG. 8F are structural diagrams of processing steps of a manufacture method for a microvalve device according to the present invention.

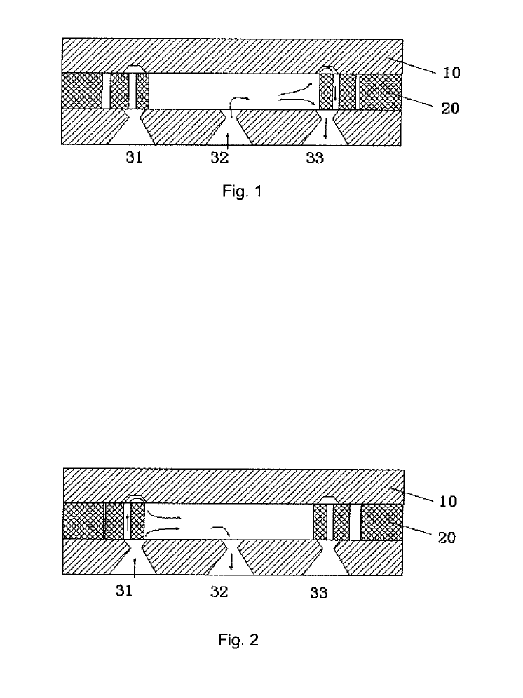

### DETAILED DESCRIPTION OF THE EMBODIMENTS

The embodiments of the present invention will be expounded below in conjunction with the accompanying drawings. However, the present invention may be implemented by various different methods limited and covered by the claims.

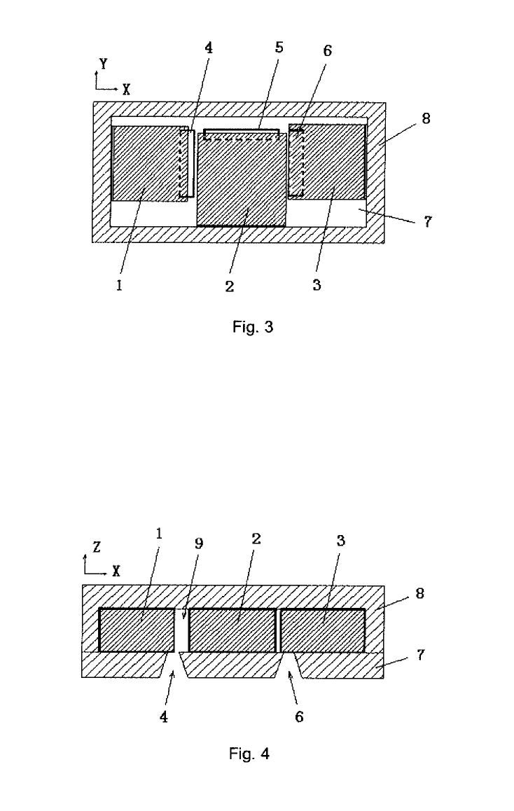

FIG. 3 to FIG. 6 show schematic diagrams of a microvalve device according to the present invention. As shown in FIG. 3 to FIG. 6, the microvalve device of the present invention is used as a pilot valve (hereinafter referred as a pilot microvalve) of a throttle expansion valve of an air-conditioning system to control a main valve of the throttle expansion valve.

The pilot microvalve comprises a body and three piezoelectric actuators, wherein the body comprises a first layer 7 and a second layer 8 forming a chamber 9 with the first layer 7, wherein the first layer 7 is provided with a first fluid port 4, a second fluid port 5, and a third fluid port 6 in fluid communication with the chamber 9; the three piezoelectric actuators are laminated in the chamber 9 and thickness directions (strain extending and retracting directions) of the piezoelectric actuators are parallel to the first layer 7, wherein a free end of a first piezoelectric actuator 4 in a strain extending and retracting direction is used for shielding the first fluid port 1, a free end of a second piezoelectric actuator 5 in a strain extending and retracting direction is used for shielding the second fluid port 2, and a free end of a third piezoelectric actuator 6 in a strain extending and retracting direction is used for shielding the third fluid port 3.

When a corresponding electric signal for opening a port is applied to a piezoelectric actuator, the piezoelectric actuator will be strained in the thickness direction, that is, the piezoelectric actuator will retract to open the corresponding port, wherein the second fluid port 5 is a control port, the first fluid port 4 is a fluid source port, and the third fluid port 6 is a reflux port. A working process of the pilot microvalve will be described below.

When only the first and second piezoelectric actuators 1 and 2 retract, the first fluid port 4 and the second fluid port 5 are opened while the third fluid port 6 maintains a closed state, and the microvalve device is in a first control state as shown in FIG. 3. It may be easily learned from FIG. 3 that, a fluid will flow into the first fluid port 4 and flow out of the second fluid port 5. That is, a fluid from a fluid source flows into the chamber 9, passes through the second fluid port 5 and flows towards a mechanism controlling the main valve. It can be hardly learned from FIG. 4 whether the second fluid port 5 is opened, and a state of the second fluid port 5 may refer to FIG. 3.

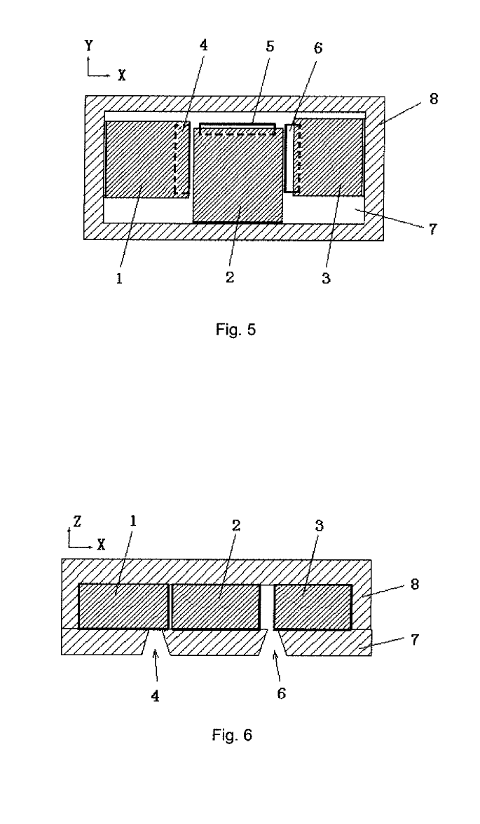

Similarly, when only the second and third piezoelectric actuators 2 and 3 retract, the second and third fluid ports 5 and 6 are opened while the first fluid port 4 is closed, and the microvalve device is in a second control state as shown in FIG. 5. It may be easily learned from FIG. 5 that a fluid will flow into the second fluid port 5 and flow out of the third fluid port 6. That is a fluid from the control mechanism of the main valve flows into the chamber and flows back through the third fluid port 6.

The first control state and the second control state above are typical modes for controlling the main valve in the present preferred embodiment, and open-loop control for an opening degree of the main valve may be implemented by controlling each fluid port separately. At the same time, linear control for an opening degree of the main valve may be controlled through controlling an opening degree of each fluid port. Notably, since closing/opening states of the three fluid ports are controlled separately, more control modes may be implemented through different combinations of control for the fluid ports.

In the present preferred embodiment, the first layer 7 is provided with a plurality of fluid ports thereon and the second layer 8 is provided with a concave structure and an electrode (not shown in the figures) is led out therefrom. The first layer 7 and the second layer 8 are combined with each other, and a side face provided with the concave structure of the second layer 8 faces to the first layer 7 so as to form the chamber 9 between the first layer 7 and the second layer 8. The first layer and the second layer may be made from silicon, but is not limited thereto.

In the present preferred embodiment, the first fluid port 4, the second fluid port 5 and the third fluid port 6 are all long strip-shaped, which may increase the sectional areas of the first fluid port 4, the second fluid port 5 and the third fluid port 6 when they are opened.

In the present preferred embodiment, the first and third fluid ports 4 and 6 are parallel to each other. The length direction of the second fluid port 5 is vertical to the length directions of the first and third fluid ports 4 and 6. The thickness directions (the strain extending and retracting directions) of the first and third piezoelectric actuators 1 and 3 are in a Y direction while the thickness direction (the strain extending and retracting direction) of the second piezoelectric actuator 2 is in an X direction, thereby reducing a plane dimension of the microvalve.

In the present preferred embodiment, a free end of each piezoelectric actuator in a strain extending and retracting direction still partly shields a fluid port at a position where retraction is terminated, thus the opening reliability of the fluid port may be improved within an effective retraction stroke of the piezoelectric actuator. Further, each fluid port is shaped as a bell mouth, and the width of an external mouth thereof is larger than the width of an internal mouth facing to the chamber, thereby further increasing the width of the fluid port.

In the present preferred embodiment, the first, second and third piezoelectric actuators are stack-type piezoelectric ceramics, and the extension and retraction amounts of the free ends of the stack-type piezoelectric ceramics in the strain extending and retracting directions may be regulated according to voltages of applied electric signals, thus implementing precise control for an opening degree of each fluid port.

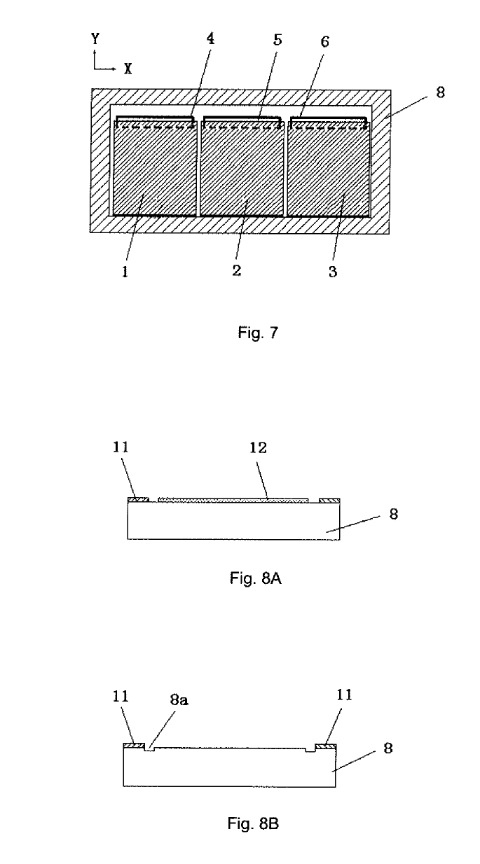

FIG. 7 is a structural diagram of a microvalve device according to another preferred embodiment of the present invention. As shown in FIG. 7, in the present preferred embodiment, the length directions of a first fluid port 4, a second fluid port 5 and a third fluid port 6 have the same orientation, i.e. the length directions all extend towards an X direction as shown in the figure. Understandably, a first fluid port 4, a second fluid port 5 and a third fluid port 6 all extend towards a Y direction as shown in the figure in another embodiment and the length directions are maintained in the same orientation. At the moment, a retaining wall is formed in a chamber to adhere and fix a fixing end of a piezoelectric actuator of the second fluid port 5.

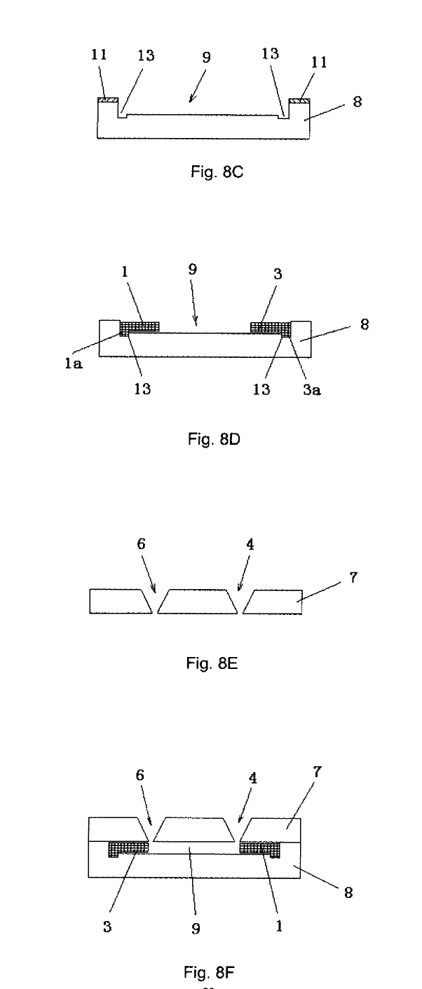

A process for manufacturing a micro-mechanism according to a preferred embodiment of the present invention will be described below with reference to FIG. 8A to FIG. 8F.

The present embodiment applies two silicon layers or wafers (e.g. 7 and 8) of a built-in piezoelectric actuator. The process enables a given Single Crystal Silicon (SCS) micro-structure to form components of a first layer and a second layer by using these two laminated silicon layers. Alternatively, the first layer and the second layer may be formed by any appropriate crystal materials, but are not limited thereto, e.g. Pyrex glass, metal or ceramic materials etc., a principle of which may be applied to formation of a micro-structure laminated by not less than two layers, but is not limited thereto.

As shown in FIG. 8A, the layer applies a photoresist material 11 and a medium material 12 (e.g. silicon oxide, silicon nitride or a combination formed by laminating the two) as mask layers which are paved in different areas to form patterns, thus limiting an alignment concave area of piezoelectric actuators in the layer.

As shown in FIG. 8B, the alignment concave area 8a of the piezoelectric actuators is formed by applying a standard semiconductor processing technology, e.g. plasma etching. The alignment concave area 8a may be provided with different geometrical shapes and required depths. In addition, the photoresist material 12 is removed while the medium material 11 is maintained.

As shown in FIG. 8C, a chamber structure 9 in the layer is formed by a Deep Reactive Ion Etching (DRIE) technology, for example.

As shown in FIG. 8D, piezoelectric actuators 1 and 3 are aligned and adhered so that locating parts la thereof are fixed in the alignment concave area 13 to further adhere fixing ends corresponding to free ends of the piezoelectric actuators to a side wall of the chamber to be combined securely to the layer.

As shown in FIG. 8E, fluid ports 4 and 6 of the other layer are formed by a standard semiconductor processing technology, e.g. DRIE, and wet etching using KOH, TMAH, or other silicon etching agents.

As shown in FIG. 8F, the two layers 7 and 8 may be formed into a secure combination using a wafer bonding technology, including, but not limited to fusion bonding, anodic bonding, solder bonding, and adhesion bonding, and so on.

Understandably, there is an extremely small gap between the free ends of the piezoelectric actuators and the two layers of substrates so that the free ends of the actuators may extend and retract freely without resistance, thereby achieving a purpose of controlling on/off or an opening degree of the fluid ports. Alternatively or additionally, the first layer and the second layer may also retract relative to the piezoelectric actuators to provide a gap therebetween. In addition, each of surfaces of the first layer and surfaces of the second layer may be intrinsic silicon or doped silicon, or covered with silicon oxide, silicon nitride, photosensitive benzocyclobutene (benzocyclobutene 4000 series, abbreviated as BCB), or any membranes that can endure combination of the layers and a processing temperature. The first layer and the second layer may be also thinned, ground and polished to a thickness required by specific application if necessary.

In the embodiments above, the fluid ports may be normally-closed ports and the free ends of the piezoelectric actuators in the strain extending and retracting directions completely shield the fluid ports in initial positions, and partly shield or fully open the fluid ports on positions where retraction is terminated. In other embodiments, the fluid ports may be normally-open ports, and the free ends of the piezoelectric actuators in the strain extending and retracting directions partly shield or fully open the fluid ports in the initial positions and fully shield the fluid ports in end positions.

In the embodiments above, the length directions of the fluid ports are oriented to the X direction or the Y direction. In other embodiments, the piezoelectric actuators and the fluid ports may be also arranged in other forms according to the same working principle, e.g. the length directions of the fluid ports have various orientations in an XY plane, e.g. an orientation is in a certain included angle with the X direction.

Microvalve devices for various purposes may be derived based on the preferred embodiments above.

In a variant embodiment, a microvalve device is used as a stop microvalve, wherein only a first fluid port and a second port are provided on a first layer of a body, and only one piezoelectric actuator is provided in a chamber of the body. The piezoelectric actuator is normally-opened and configured to close the first fluid port and the second fluid part to implement a function of a stop valve.

In another variant embodiment, a microvalve device is used as a pilot microvalve, wherein a first fluid port, a second fluid port and a third fluid port are provided on a first layer of a body, and a first piezoelectric actuator and a third piezoelectric actuator are provided in a chamber of the body to control the first fluid port and the third fluid port, respectively, while it is unnecessary to provide a piezoelectric actuator for the second fluid port.

In still another variant embodiment, a microvalve device is used as a reversing microvalve, wherein a first layer of a body is provided with a plurality of fluid ports thereon, e.g. three fluid ports, four fluid ports, or five fluid ports, and so son, and a piezoelectric actuator is provided in a chamber of the body to control a fluid port which requires control of opening and closing. In an initial position, a free end of a corresponding piezoelectric actuator in a strain extending and retracting direction may be in a state of closing a normally-closed fluid port, and in an initial position, a free end of a corresponding piezoelectric actuator in a strain extending and retracting direction may be in a state of opening a normally-open fluid port, thereby implementing various functions of the reversing microvalve.

In still another variant embodiment, other structures or components may be further provided in a chamber of a body of a microvalve device.

A microvalve device is provided in still another variant embodiment. The microvalve device is arranged in an external flow channel and used as a stop valve, thus it is unnecessary to form a chamber. The microvalve device comprises a first layer provided with fluid ports, and laminated piezoelectric actuators provided on one side of the first layer. Strain extending and retracting directions of the piezoelectric actuators are parallel to the first layer. Free ends of the piezoelectric actuators in the strain extending and retracting directions are used for shielding the fluid ports so as to control opening/closing states of the fluid ports.

The foregoing descriptions are only preferred embodiments of the present invention and are not used for limiting the present invention. For those skilled in the art, the present invention may have various alternations and changes. All modifications, equivalent replacements and improvements and the like made within the spirit and principle of the present invention shall be included within the protection scope of the present invention.

1. A microvalve device, comprising:
a body, at least comprising a first layer and a second layer forming a chamber with the first layer, wherein the first layer is provided with at least two fluid ports in fluid communication with the chamber; and piezoelectric actuators corresponding to predetermined fluid ports,
wherein the piezoelectric actuators are arranged in the chamber and strain extending and retracting directions of the piezoelectric actuators are parallel to the first layer, wherein free ends of the piezoelectric actuators in the strain extending and retracting directions are used for shielding the fluid ports so as to control opening/closing states of the fluid ports.

2. The microvalve device according to claim 1, wherein the fluid ports are long strip-shaped, and the length directions of the fluid ports are vertical to the strain extending and retracting directions of the piezoelectric actuators.

3. The microvalve device according to claim 2, wherein the length directions of the fluid ports have the same orientation.

4. The microvalve device according to claim 1, wherein the fluid ports are partly opened or fully opened by the free ends of the piezoelectric actuators in the strain extending and retracting directions when the fluid ports are opened.

5. The microvalve device according to claim 1, wherein the piezoelectric actuators are stack-type piezoelectric ceramics and the thickness directions of the stack-type piezoelectric ceramics are parallel to the first layer.

6. The microvalve device according to claim 1, wherein an opening width of one side of the fluid ports on the first layer which faces to the chamber is smaller or equal to an opening width of one side of the fluid ports on the first layer which faces to outside.

7. The microvalve device according to claim 1, wherein a free end of a second piezoelectric actuator in a strain extending and retracting direction is further used for controlling an opening degree of a second fluid port precisely.

8. The microvalve device according to claim 1, wherein the microvalve device is a pilot microvalve.

9. The microvalve device according to claim 8, wherein the first layer is provided with a first fluid port, the second fluid port and a third fluid port, wherein the first fluid port is a fluid source port, the second fluid port is a control port, and the third fluid port is a reflux port, wherein at least a first piezoelectric actuator corresponding to the first fluid port and a third piezoelectric actuator corresponding to the third fluid port are arranged in the chamber.

10. The microvalve device according to claim 9, wherein a second piezoelectric actuator corresponding to the second fluid port is arranged in the chamber, wherein the first fluid port and the third fluid port are arranged in parallel at an interval, the second fluid port is located between the first fluid port and the third fluid port, and a length direction of the second fluid port is vertical to a length direction of the first fluid port.

11. The microvalve device according to claim 1, wherein the microvalve device is a reversing microvalve.

12. The microvalve device according to claim 1, wherein the microvalve device is a stop microvalve.

13. The microvalve device according to claim 1, wherein the body only comprises the first layer provided with the fluid ports and the second layer forming the chamber, wherein a bottom wall of the chamber of the second layer is provided with alignment concave areas thereon, and the piezoelectric actuators are provided with locating parts located in the alignment concave areas.

14. The microvalve device according to claim 13, wherein the piezoelectric actuators are adhesively fixed to the second layer.

15. A manufacturing method for a microvalve device, comprising the following steps:
manufacturing a first layer provided with at least two fluid ports;
manufacturing a second layer provided with a chamber;
placing piezoelectric actuators in the chamber of the second layer, and aligning and adhering the piezoelectric actuators with the second layer; and
combining the first layer and the second layer to form the microvalve device, wherein strain extending and retracting directions of the piezoelectric actuators are parallel to the first layer, wherein free ends of the piezoelectric actuators in the strain extending and retracting directions are used for shielding the fluid ports so as to control opening/closing states of the fluid ports.

16. The manufacturing method according to claim 15, wherein the step of manufacturing the second layer provided with the chamber further comprises forming alignment concave areas of the piezoelectric actuators on a bottom wall of the chamber,.

17. A microvalve device, comprising a first layer provided with fluid ports and laminated piezoelectric actuators arranged at one side of the first layer;
strain extending and retracting directions of the piezoelectric actuators are parallel to the first layer; free ends of the piezoelectric actuators in the strain extending and retracting directions are used for shielding the fluid ports so as to control opening/closing states of the fluid ports.
